(19) United States
(12) Patent Application Publication
(10) Pub. No.: US 2007/0210420 A1
(43) Pub. Date: Sep. 13, 2007

(54) Laser delamination of thin metal film using sacrificial polymer layer

(76) Inventors: Curt Lee Nelson, Corvallis, OR (US); Ronald A. Hellekson, Corvallis, OR (US); Peter S. Nyholm, Corvallis, OR (US); Michael French, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/372,555

(22) Filed: Mar. 11, 2006

(51) Int. Cl. H01L 29/40; H01L 21/465

(52) U.S. Cl. 257/632; 438/669; 438/720; 257/734

(57) ABSTRACT

A plastic substrate is provided, on which is disposed a sacrificial polymer layer and a thin metal film over the sacrificial polymer layer. The thin metal film is laser-delamination patterned. The sacrificial polymer layer is at least partially removed via laser delamination where the thin metal film has been removed via laser delamination.

### BACKGROUND

Traditionally, patterning of semiconductor-oriented devices is accomplished by using photolithography. However, such patterning of devices in which there is a thin metal film on a plastic substrate can be disadvantageous. In particular, the photolithographic process can be very slow for such devices.

Therefore, more recently, laser delamination has been employed to pattern thin metal films on plastic substrates. Laser delamination is advantageous because it can be performed more quickly than traditional photolithography. However, laser delamination is disadvantageous in that it roughens the surfaces of the channels formed during patterning, including the surface of the underlying exposed plastic substrate.

### BRIEF DESCRIPTION OF THE DRAWINGS

The drawings referenced herein form a part of the specification. Features shown in the drawing are meant as illustrative of only some embodiments of the invention, and not of all embodiments of the invention, unless otherwise explicitly indicated.

FIG. 1 is a flowchart of a method for at least partially fabricating an electronic device, including performing laser-delamination patterning, according to an embodiment of the invention.

FIGS. 2-7 are diagrams depicting example and illustrative performance of various parts of the method of FIG. 1, according to differing embodiments of the invention.

### DETAILED DESCRIPTION OF THE DRAWINGS

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

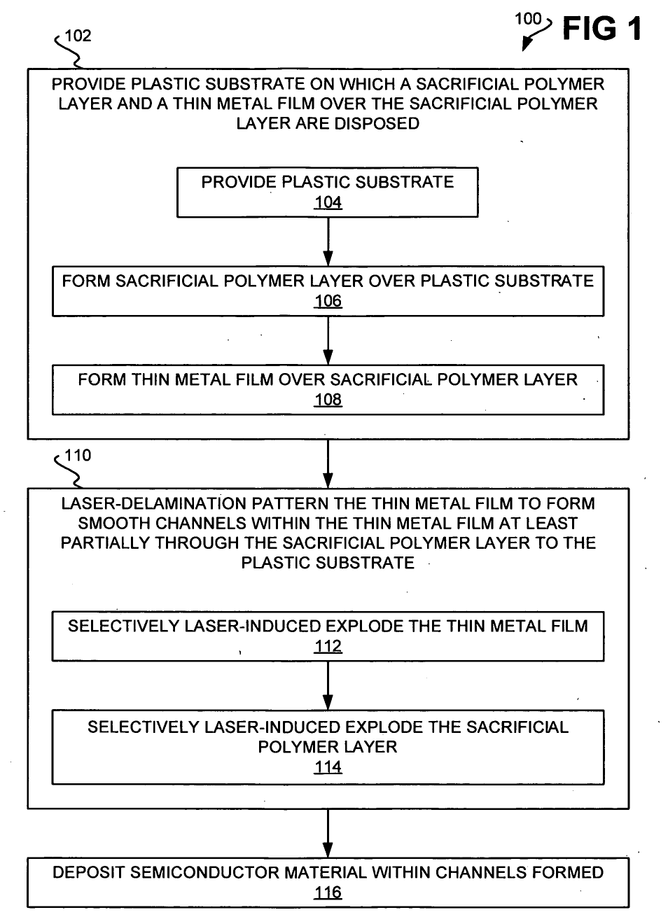

FIG. 1 shows a method 100 for at least partially fabricating an electronic device, according to an embodiment of the invention. The electronic device exemplarily fabricated by performing the method 100 is a thin-film transistor (TFT). However, as can be appreciated by those of ordinary skill within the art, the method 100 may be performed in whole or in part to form other types of electronic devices.

A plastic substrate is provided, on which a sacrificial polymer layer and a thin metal film over the sacrificial polymer layer are disposed (102). In one embodiment, part 102 of the method 100 is performed as follows. First, a plastic substrate is provided (104). The plastic substrate may be polyethyleneterephthalate (PET), polyethylenenaphthalate (PEN), polyamide, polyether, polysulfone, polyethersulfone (PES), polycarbonate, polyarylate, polyetherimide, polyetheretherketone (PEEK), polyimide, polyparabanic acid, or another type of plastic substrate.

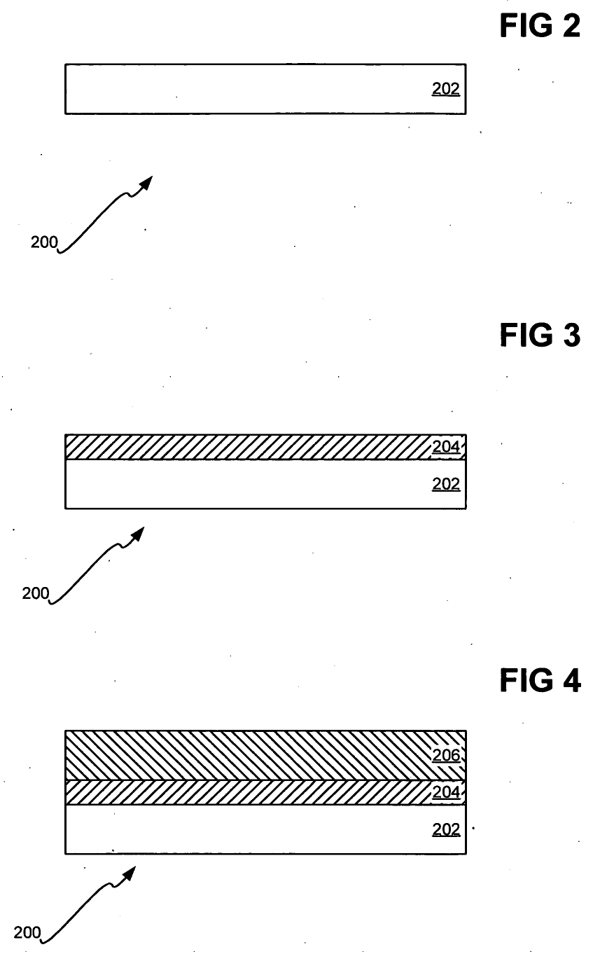

FIG. 2 shows representative and illustrative performance of part 104 of the method 100, according to an embodiment of the invention. An electronic device 200 is being fabricated. As part of the electronic device 200, a plastic substrate 202 has been provided.

Referring back to FIG. 1, a sacrificial polymer layer is formed over the plastic substrate (106). The sacrificial polymer layer may be photoresist, such as SU8 photoresist, as known to those of ordinary skill within the art, or another type of polymer. It is noted that the photoresist is not used for photolithographic purposes, as is conventional, but rather is used as a readily available polymer that can be applied to the substrate using known techniques. For example, the sacrificial polymer layer may be coated over the plastic substrate, such as by spincoating, curtain coating, lamination, or by another technique. The polymer layer is referred to as a sacrificial polymer layer for reasons that are described later in the detailed description.

FIG. 3 shows representative and illustrative performance of part 106 of the method 100, according to an embodiment of the invention. As before, the electronic device 200 is being fabricated. As part of the electronic device 200, a sacrificial polymer layer 204 has been formed over the plastic substrate 202. In one embodiment, the sacrificial polymer layer 204 has a thickness of 0.1 micron.

Referring back to FIG. 1, a thin metal film is formed over the sacrificial polymer layer (108). The thin metal film may be aluminum, silver, copper, gold, tantalum, titanium, or another metal, or an alloy of two or more such metals. The thin metal film may be formed using a variety of different techniques, such as chemical vapor deposition (CVD), sputtering, flash plating, and so on. The thin metal film is formed over the sacrificial polymer layer in one embodiment such that the sacrificial polymer layer at least substantially adheres to the thin metal film.

FIG. 4 shows representative and illustrative performance of part 108 of the method 100, according to an embodiment of the invention. The electronic device 200 is being fabricated. As part of the electronic device, a thin metal film 206 has been formed over the sacrificial polymer layer 204 previously formed on the plastic substrate 202. In one embodiment, the thin metal film 206 has a thickness of 100 nanometers (nm) or less.

Referring back to FIG. 1, the thin metal film is laser-delamination patterned as desired to form one or more smooth channels within the thin metal film (110). The laser-delamination process occurs at least partially through the sacrificial polymer layer. In one embodiment, some of the sacrificial polymer layer remains within the channel. For instance, the sacrificial polymer layer may not have been exposed to sufficient energy to be completely ablated, which can be desirable where the sacrificial polymer layer itself has a smooth surface upon partial ablation. In another embodiment, all of the sacrificial polymer layer is removed from the channel as a result of laser-delamination patterning. For instance, the sacrificial polymer layer may itself have a rough surface if it is just partially ablated, such that it is exposed to sufficient energy to be completely removed so that such a rough surface of the sacrificial polymer layer does not result.

Laser-delamination patterning can be performed by selectively exposing the thin metal film, and thus the underlying sacrificial polymer layer, to one or more pulses of a laser. For instance, the laser may be a laser having a wavelength of 248 nm, 308 nm, 355 nm, 532 nm, 1064 nm, at a fluence up to one Joule per square centimeter (J/cm²), in one embodiment of the invention. The laser may be turned on for a length of time equal to a single shot of less than or equal to thirty nanoseconds (ns) in one embodiment.

Therefore, in one embodiment, laser-delamination patterning results in the following. First, the thin metal film is selectively laser-induced exploded (112). Explosion in this context can include and encompass vaporization and decomposition of the thin metal film to cause its removal. At these same locations of the electronic device being fabricated, the sacrificial polymer layer is also selectively laser-induced exploded (114). Likewise, explosion in this context can include and encompass vaporization and decomposition of the sacrificial polymer layer to cause its at least partial removal. It is noted that while parts 112 and 114 are described herein separately, this is for descriptive purposes only. In actuality, the thin metal film is photochemically and/or photothermally ablated at the same time that the sacrificial polymer layer is photochemically and/or photothermally ablated exploded. That is, in the same exposure to a laser, both the thin metal film and the sacrificial polymer layer are removed.

It is noted that this process is unlike the prior art, such as that described in U.S. Pat. No. 6,617,541, issued to Wadman et al. In the Wadman patent, for instance, an underlying “assist layer” is exploded, the explosion of which causes removal of the overlying thin metal film. That is, in Wadman, the thin metal film is itself not exploded, but rather is removed as a result of the removal of the underlying assist layer. By comparison, in at least some embodiments of the invention, both the thin metal film and the sacrificial polymer layer are exploded via laser inducement.

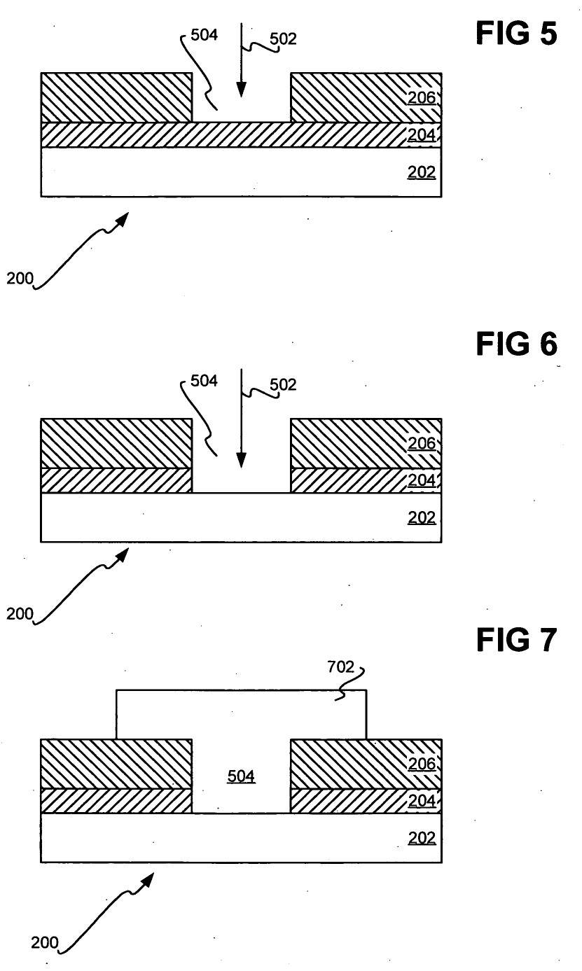

FIGS. 5 and 6 show representative and illustrative performance of parts 112 and 114 of the method 100, according to varying embodiments of the invention. In FIG. 5, the electronic device 200 continues to be fabricated. A laser 502 is positioned incident to a desired location of the thin metal film 206 at which a channel 504 is to be formed. The laser 502 etches, or otherwise removes or delaminates the thin metal film 206 at this location, resulting in the channel 504 being formed through the thin metal film 206.

In FIG. 6, the laser 502 continues to be positioned incident to the channel 504. The laser 502 etches, or otherwise removes or delaminates the sacrificial polymer layer 204. In FIG. 6, the sacrificial polymer layer 204 is completely removed from the channel 504 through to the plastic substrate 202, although in another embodiment, at least a portion of the sacrificial polymer layer 204 may remain within the channel 504. Furthermore, whereas in FIGS. 5 and 6 just one channel 504 has been formed, in other embodiments more than one such channel can be formed via laser-delamination patterning. The entire process depicted in FIGS. 5 and 6 can occur in a single shot of the laser 502, for a length of time in which it is positioned incident to the channel 504 being formed.

It has been found that the presence of the sacrificial polymer layer 204 during the laser-delamination patterning process provides for smoother surfaces of the channel 504 than if the sacrificial polymer layer 204 were absent during the laser-delamination patterning process. These smoother surfaces of the channel 504 include the sidewalls of the channel 504, such as those of the thin metal film 206, as well as the floor of the channel 504, such as that of the plastic substrate 202. For instance, where the thin metal film 206 is aluminum, it has been found that a surface roughness factor known within the art as Rq may be within the range of 20-80 nm without the sacrificial polymer layer 204. However, where the sacrificial polymer layer 204 is present, the surface roughness factor Rq decreases to 4 nm, a reduction in roughness of at least 80%.

Therefore, the sacrificial polymer layer 204 is sacrificial in the sense that it is present just to be at least partially removed during laser-delamination patterning, so that the surfaces of the channel that is formed are smoother than they would otherwise be if the layer 204 were not present. That is, the primary, if not only, function of the sacrificial polymer layer 204 is to be at least partially removed during laser-delamination patterning, to cause smoother channels during the laser-delamination patterning process. The sacrificial polymer layer 204 in at least some embodiments has no other functionality or purpose other than this sacrificial functionality and purpose.

In one embodiment, the heat-absorption characteristics of the sacrificial polymer layer 204 are matched to the wavelength of the laser 502 being used, such that the sacrificial polymer layer 204 is heated and ultimately vaporized or otherwise decomposed during laser-delamination patterning. However, it has been found that, in another embodiment, the heat-absorption characteristics of the sacrificial polymer layer 204 may be specifically not matched, or unmatched, to the wavelength of the laser 502 being used. As such, the sacrificial polymer layer 204 is not directly heated by the laser 502. In this embodiment, too, however, it has been found that the utilization of such a sacrificial polymer layer 204 nevertheless results in smoother channels being formed.

Referring back to FIG. 1, in one embodiment a semiconductor material may be deposited within the channels that have been formed (116). For instance, the deposition of such a semiconductor material can result in thin-film transistors being formed as the electronic devices fabricated as a result of performance of the method 100. The semiconductor material may be an organic or inorganic semiconductor, or another type of semiconductor material.

FIG. 7 shows representative and illustrative performance of part 116 of the method 100, according to an embodiment of the invention. A semiconductor material 702 has been deposited within and over the channel 504, and makes electrical contact with both sides of the thin metal film 206. Thus, both sides of the thin metal film 206 and the semiconductor material 702 together partially form a thin-film transistor as the electronic device 200 that has been fabricated. It is noted that the sacrificial polymer layer 204 serves no operable function within this transistor, as is present just to have smoother channel sidewalls during laser-delamination patterning, as has been described.

It is noted that although specific embodiments have been illustrated and described herein, it will be appreciated by those of ordinary skill in the art that any arrangement calculated to achieve the same purpose may be substituted for the specific embodiments shown. This application is intended to cover any adaptations or variations of the disclosed embodiments of the present invention. It is thus manifestly intended that this invention be limited only by the claims and equivalents thereof.

We claim:

1. A method comprising:
providing a plastic substrate on which is disposed a sacrificial polymer layer and a thin metal film over the sacrificial polymer layer; and,
laser-delamination patterning the thin metal film, such that the sacrificial polymer layer is at least partially removed via laser delamination where the thin metal film has been removed via laser delamination.

2. The method of claim 1, wherein laser-delamination patterning the thin metal film comprises forming one or more channels, such that presence of the sacrificial polymer layer results in surfaces of the channels being smoother than would otherwise occur without the sacrificial polymer layer.

3. The method of claim 1, wherein the sacrificial polymer layer primarily functions to cause smooth channels resulting from laser-delaminating patterning.

4. The method of claim 1, wherein the sacrificial polymer layer is completely removed where the thin metal film has been removed.

5. The method of claim 1, wherein the sacrificial polymer layer is matched to a wavelength of a laser used in the laser-delamination patterning such that the sacrificial polymer layer is heated by the laser.

6. The method of claim 1, wherein the sacrificial polymer layer is particularly unmatched to a wavelength of a laser used in the laser-delamination patterning such that the sacrificial polymer layer is not heated by the laser.

7. The method of claim 1, wherein laser-delamination patterning the thin metal film comprises selectively exposing the thin metal film to one or more pulses of a laser.

8. The method of claim 1, wherein laser-delamination patterning the thin metal film comprises:
selectively laser-induced exploding the thin metal film; and,
selectively laser-induced exploding the sacrificial polymer layer.

9. The method of claim 1, wherein providing the plastic substrate on which is disposed the sacrificial polymer layer and the thin metal film over the sacrificial polymer layer comprises:
providing the plastic substrate;
forming the sacrificial polymer layer over the plastic substrate; and,
forming the thin metal film over the sacrificial polymer layer, where the sacrificial polymer layer at least substantially adheres to the thin metal film.

10. The method of claim 9, wherein forming the sacrificial polymer layer comprises coating polymer onto the plastic substrate to result in the sacrificial polymer layer.

11. The method of claim 9, wherein forming the thin metal film over the sacrificial polymer layer comprises depositing metal particles onto the sacrificial polymer layer to result in the thin metal film.

12. The method of claim 1, wherein the plastic substrate is one of: polyethyleneterephthalate (PET), polyethylenenaphthalate (PEN), polyamide, polyether, polysulfone, polyethersulfone (PES), polycarbonate, polyarylate, polyetherimide, polyetheretherketone (PEEK), polyimide, and polyparabanic acid.

13. The method of claim 1, wherein the sacrificial polymer layer is photoresist.

14. The method of claim 13, wherein the photoresist is SU8 photoresist.

15. The method of claim 1, wherein the thin metal film is one of: aluminum, silver, copper, gold, tantalum, and titanium.

16. The method of claim 1, wherein the thin metal film is an alloy of two or more of: aluminum, silver, copper, gold, tantalum, and titanium.

17. A method comprising:
providing a plastic substrate on which is disposed a sacrificial polymer layer and a thin metal film over the sacrificial polymer layer; and,
forming smooth channels within the thin metal film through the sacrificial polymer layer to the plastic substrate via laser delamination of the thin metal film and the sacrificial polymer layer,
wherein presence of the sacrificial polymer layer results in formation of the smooth channels.

18. The method of claim 17, wherein forming the channels within the thin metal film comprises:
selectively laser-induced exploding the thin metal film; and,
selectively laser-induced exploding the sacrificial polymer layer.

19. The method of claim 17, wherein the sacrificial polymer layer is photoresist.

20. An electronic device formed at least in part by performing a method comprising:
providing a plastic substrate on which is disposed a sacrificial polymer layer and a thin metal film over the sacrificial polymer layer; and,
laser-delamination patterning the thin metal film, such that the sacrificial polymer layer is at least partially removed via laser delamination where the thin metal film has been removed via laser delamination.

21. The electronic device of claim 20, wherein laser-delaminating patterning the thin metal film comprises forming one or more channels, such that presence of the sacrificial polymer layer results in surfaces of the channels being smoother than would otherwise occur without the sacrificial polymer layer.

22. The electronic device of claim 20, wherein the sacrificial polymer layer primarily functions to cause smooth channels resulting from laser-delaminating patterning.

23. The electronic device of claim 20, wherein the sacrificial polymer layer is completely removed where the thin metal film has been removed.

24. The electronic device of claim 20, wherein laser-delamination patterning the thin metal film comprises:
selectively laser-induced exploding the thin metal film; and,
selectively laser-induced exploding the sacrificial polymer layer.

25. The electronic device of claim 20, wherein laser-delamination patterning the thin metal film forms one or more channels, the method further comprising depositing a semiconductor material within each channel, such that the electronic device comprises one or more thin-film transistors (TFT's).

26. The electronic device of claim 20, wherein the plastic substrate is one of: polyethyleneterephthalate (PET), polyethylenenaphthalate (PEN), polyamide, polyether, polysulfone, polyethersulfone (PES), polycarbonate, polyarylate, polyetherimide, polyetheretherketone (PEEK), polyimide, and polyparabanic acid.

27. The electronic device of claim 20, wherein the sacrificial polymer layer is photoresist.

28. The electronic device of claim 20, wherein the thin metal film is one of: aluminum, silver, copper, gold, tantalum, and titanium.

29. The electronic device of claim 20, wherein the thin metal film is an alloy of two or more of: aluminum, silver, copper, gold, tantalum, and titanium.
